(19) United States
(12) Patent Application Publication
(10) Pub. No.: US 2015/0015113 A1
(43) Pub. Date: Jan. 15, 2015

(54) POLYMER ACTUATOR DEVICE AND APPARATUS AND METHOD FOR DRIVING POLYMER ACTUATOR DEVICE

(71) Applicants: ALPS ELECTRIC CO., LTD., Tokyo (JP); National Institute of Advanced Industrial Science and Technology, Tokyo (JP); STELLA CHEMIFA CORPORATION, Osaka City (JP)

(72) Inventors: Yorihiko SASAKI, Miyagi-ken (JP); Teppei SUGAWARA, Miyagi-ken (JP); Nobuaki HAGA, Miyagi-ken (JP); Kinji ASAKA, Tokyo (JP); Takushi SUGINO, Tokyo (JP); Tetsuo NISHIDA, Osaka (JP)

(21) Appl. No.: 14/447,348

(22) Filed: Jul. 30, 2014

Related U.S. Application Data
(63) Continuation of application No. PCT/JP2013/052147, filed on Jan. 31, 2013.

(30) Foreign Application Priority Data
Feb. 8, 2012 (JP) 2012-024690

(51) Int. Cl. H01L 41/193; H01L 41/04; H01L 41/047

(52) U.S. Cl. CPC H01L 41/193; H01L 41/0471; H01L 41/0478; H01L 41/042
USPC 310/317; 310/366; 310/363

(57) ABSTRACT

A polymer actuator device includes a device part including an electrolyte layer, first and second electrode layers disposed on either surface of the electrolyte layer in a thickness direction, and a reference electrode layer disposed between the first and second electrode layers and in contact with the electrolyte layer. The device part bends in response to a voltage applied between the first and second electrode layers.

### CLAIM OF PRIORITY

This application is a Continuation of International Application No. PCT/JP2013/052147 filed on Jan. 31, 2013, which claims benefit of Japanese Patent Application No. 2012-024690 filed on Feb. 8, 2012. The entire contents of each application noted above are hereby incorporated by reference.

### BACKGROUND OF THE INVENTION

1. Field of the Invention

The present invention relates to polymer actuator devices that bend when a voltage is applied thereto.

2. Description of the Related Art

Japanese Unexamined Patent Application Publication No. 2008-34268 discloses an invention related to a polymer actuator. This polymer actuator includes an electrolyte layer and a pair of electrode layers disposed on either side of the electrolyte layer in the thickness direction. The polymer actuator bends when a voltage is applied between the pair of electrode layers at a fixed end thereof.

During operation, the voltage (potential difference) is precisely controlled by a potentiostat. After extended operation, however, a potential shift occurs, for example, due to changes near the electrodes or in the electrodes themselves. This potential shift causes the polymer actuator, which is initially driven within the potential window (threshold at which electrolysis occurs) of the ionic liquid contained in the electrode layers and the electrolyte layer, to be driven beyond the potential window of the ionic liquid, thus causing the electrolysis of the ionic liquid. The electrolysis of the ionic liquid results in decreased device reliability, including a deviation from the initial displacement position (displacement) for the same applied voltage, and also results in a shortened device life.

In particular, a configuration including electrode layers containing a nanocarbon material, which has a large specific surface area and various active sites, tends to suffer from the above problems because the potential window of the ionic liquid is narrowed.

### SUMMARY OF THE INVENTION

The present invention provides a polymer actuator device including a bending device part that can be stably driven and an apparatus and method for driving such a polymer actuator device.

According to an aspect of the present invention, there is provided a polymer actuator device. This device includes a device part including an electrolyte layer, first and second electrode layers disposed on either surface of the electrolyte layer in a thickness direction, and a reference electrode layer disposed between the first and second electrode layers and in contact with the electrolyte layer. The device part bends in response to a voltage applied between the first and second electrode layers.

According to another aspect of the present invention, there is provided an apparatus for driving a polymer actuator device. This apparatus includes the above polymer actuator device and a potentiostat configured to drive the device part. One of the first and second electrode layers serves as a working electrode. The other of the first and second electrode layers serves as a counter electrode. The reference electrode layer has a reference potential.

According to another aspect of the present invention, there is provided a method for driving a polymer actuator device. This method includes driving the device part of the above polymer actuator device using a potentiostat. One of the first and second electrode layers serves as a working electrode. The other of the first and second electrode layers serves as a counter electrode. The reference electrode layer has a reference potential. In this aspect, the device part may be driven at constant potential.

As described above, the polymer actuator device has a three-electrode structure including the reference electrode layer, which has a reference potential. This prevents a potential shift such as occurs in a two-electrode structure in the related art, thus providing stable operating characteristics (e.g., stable displacement position during bending and stable return position).

In the above aspects, the reference electrode layer disposed between the first and second electrode layers preferably has a smaller area than the first and second electrode layers. Such a reference electrode layer does not interfere with the bending motion of the device part and thus allows the polymer actuator device to be properly driven.

In the above aspects, the device part preferably includes a fixed portion at which the device part is fixed and supported at one end thereof and a bending portion at another end thereof. The reference electrode layer disposed between the first and second electrode layers preferably extends in a longitudinal direction being a direction from the fixed portion toward the bending portion. The width of the reference electrode layer in a lateral direction perpendicular to the longitudinal direction is preferably smaller than the width of the first and second electrode layers. This simplifies the structure of the reference electrode layer.

In the above aspects, a portion of the device part preferably has a five-layer structure in which the electrolyte layer is disposed between the reference electrode layer and the first electrode layer and between the reference electrode layer and the second electrode layer.

In the above aspects, the reference electrode layer is preferably made of a flexible material. If such a reference electrode layer is provided in the bending portion, the device part can bend properly while a potential shift is effectively prevented in the bending portion, thus providing more stable operating characteristics.

In the above aspects, the device part preferably includes a fixed portion at which the device part is fixed and supported at one end thereof and a bending portion at another end thereof, and the reference electrode layer preferably extends between the ends of the fixed portion and the bending portion. This allows the reference electrode layer to be easily provided and also effectively prevents a potential shift over the entire device part, thus providing more stable operating characteristics.

In the above aspects, the reference electrode layer preferably extends outward of the fixed portion. A surface of the reference electrode layer at the end of the bending portion is preferably substantially in flush with surfaces of the first and second electrode layers at the end of the bending portion. The electrolyte layer preferably extends outward of the surface of the reference electrode layer at the end of the bending portion and outward of surfaces of the first and second electrode layers at the end of the fixed portion. This prevents a short circuit between the first electrode layer, the second electrode layer, and the reference electrode layer at the ends of the bending portion and the fixed portion.

In the above aspects, the first electrode layer, the second electrode layer, and the reference electrode layer are preferably made of the same material. In this case, the first electrode layer, the second electrode layer, and the reference electrode layer preferably contain carbon nanotubes. This allows the electrode layers to have the same electrode characteristics and thus prevents the reference electrode layer from interfering with ion migration through the electrolyte layer between the first and second electrode layers. In addition, as described above, the reference electrode layer can be made of a flexible material so that the device part can bend properly. Furthermore, improved manufacturing efficiency and reduced manufacturing costs can be achieved.

In the above aspects, the first electrode layer, the second electrode layer, the reference electrode layer, and the electrolyte layer preferably contain the same ionic liquid. That is, the entire device part may contain the same ionic liquid. This allows the driving potential to be set within the potential window of the ionic liquid, thus providing stable operating characteristics.

### BRIEF DESCRIPTION OF THE DRAWINGS

FIG. 1A is a plan view of a polymer actuator device according to an embodiment of the present invention, FIG. 1B is a longitudinal sectional view taken along line IB-IB in FIG. 1A in the thickness direction as viewed from the direction indicated by the arrows in FIG. 1A, and FIG. 1C is a longitudinal sectional view taken along line IC-IC in FIG. 1A in the thickness direction as viewed from the direction indicated by the arrows in FIG. 1A;

FIG. 2 is a circuit diagram of an apparatus for driving the polymer actuator device according to the embodiment;

FIGS. 3A to 3E are cyclic voltammograms (CV) obtained with varying widths of reference electrode layers;

FIGS. 4A and 4B are longitudinal sectional views of polymer actuator devices of comparative examples;

FIG. 5A is a cyclic voltammogram (CV) of a polymer actuator device of an inventive example, and FIG. 5B is a cyclic voltammogram (CV) of the polymer actuator device of the comparative example in FIG. 4A; and

FIG. 6A is a graph showing experimental results of the displacement and current cyclic characteristics of an inventive example (three-electrode structure), and FIG. 6B is a graph showing experimental results of the displacement and current cyclic characteristics of a comparative example (two-electrode structure).

### DESCRIPTION OF THE PREFERRED EMBODIMENTS

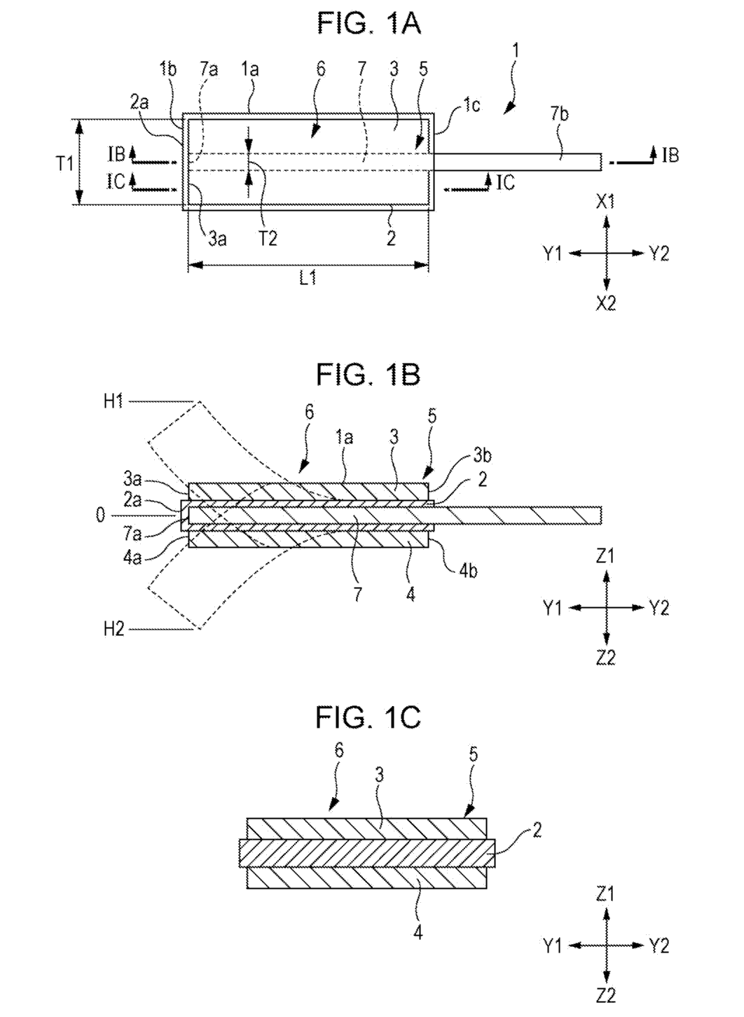

FIG. 1A is a plan view of a polymer actuator device according to an embodiment of the present invention. FIG. 1B is a longitudinal sectional view taken along line IB-IB in FIG. 1A in the thickness direction. FIG. 1C is a longitudinal sectional view taken along line IC-IC in FIG. 1A in the thickness direction.

As shown in FIGS. 1A to 1C, a polymer actuator device 1 according to this embodiment includes a device part 1a including an electrolyte layer (ion-conducting layer) 2 and first and second electrode layers 3 and 4 disposed on either surface of the electrolyte layer 2 in the thickness direction (Z1-Z2).

In the polymer actuator device 1 according to this embodiment, the electrolyte layer 2 contains an ionic liquid and a base polymer, and the electrode layers 3 and 4 contain carbon nanotubes, a base polymer, and an ionic liquid.

Examples of base polymers include polyvinylidene fluoride-based polymers and polymethyl methacrylate (PMMA)-based polymers. Particularly preferred are polyvinylidene fluoride-based polymers.

Examples of ionic liquids include ethylmethylimidazolium tetrafluoroborate (EMIBF4) and ethylmethylimidazolium bis(trifluoromethanesulfonyl)imide (EMITFSI).

Examples of ionic liquids that may be used in the present invention include various combinations of cations and anions, which may be used alone or in combination. Examples of ammonium cations that may be used in the present invention include, but not limited to, tetraalkylammonium cations, tetraalkylphosphonium cations, imidazolium cations, pyrazolium cations, pyridinium cations, triazolium cations, pyridazinium cations, thiazolium cations, oxazolium cations, pyrimidinium cations, and pyrazinium cations.

Examples of tetraalkylammonium cations include, but not limited to, tetraethylammonium, tetramethylammonium, tetrapropylammonium, tetrabutylammonium, triethylmethylammonium, trimethylethylammonium, dimethyldiethylammonium, trimethylpropylammonium, trimethylbutylammonium, dimethylethylpropylammonium, methylethylpropylbutylammonium, N,N-dimethylpyrrolidinium, N-ethyl-N-methylpyrrolidinium, N-methyl-N-propylpyrrolidinium, N-ethyl-N-propylpyrrolidinium, N,N-dimethylpiperidinium, N-methyl-N-ethylpiperidinium, N-methyl-N-propylpiperidinium, N-ethyl-N-propylpiperidinium, N,N-dimethylmorpholinium, N-methyl-N-ethylmorpholinium, N-methyl-N-propylmorpholinium, N-ethyl-N-propylmorpholinium, trimethylmethoxymethylammonium, dimethylethylmethoxymethylammonium, dimethylpropylmethoxymethylammonium, dimethylbutylmethoxymethylammonium, diethylmethylmethoxymethylammonium, methylethylpropylmethoxymethylammonium, triethylmethoxymethylammonium, diethylpropylmethoxymethylammonium, diethylbutylmethoxymethylammonium, dipropylmethylmethoxymethylammonium, dipropylethylmethoxymethylammonium, tripropylmethoxymethylammonium, tributylmethoxymethylammonium, trimethylethoxymethylammonium, dimethylethylethoxymethylammonium, dimethylpropylethoxymethylammonium, dimethylbutylethoxymethylammonium, diethylmethylethoxymethylammonium, triethylethoxymethylammonium, diethylpropylethoxymethylammonium, diethylbutylethoxymethylammonium, dipropylmethylethoxymethylammonium, dipropylethylethoxymethylammonium, tripropylethoxymethylammonium, tributylethoxymethylammonium, N-methyl-N-methoxymethylpyrrolidinium, N-ethyl-N-methoxymethylpyrrolidinium, N-propyl-N-methoxymethylpyrrolidinium, N-butyl-N-methoxymethylpyrrolidinium, N-methyl-N-ethoxymethylpyrrolidinium, N-methyl-N-propoxymethylpyrrolidinium, N-methyl-N-butoxymethylpyrrolidinium, N-methyl-N-methoxymethylpiperidinium, N-ethyl-N-methoxymethylpyrrolidinium, N-methyl-N-ethoxymethylpyrrolidinium, N-propyl-N-methoxymethylpyrrolidinium, and N-methyl-N-propoxymethylpyrrolidinium. Examples of tetraalkylphosphonium cations include tetraethylphosphonium, tetramethylphosphonium, tetrapropylphosphonium, tetrabutylphosphonium, triethylmethylphosphonium, trimethylethylphosphonium, dimethyldiethylphosphonium, trimethylpropylphosphonium, trimethylbutylphosphonium, dimethylethylpropylphosphonium, and methylethylpropylbutylphosphonium.

Examples of imidazolium cations include, but not limited to, 1,3-dimethylimidazolium, 1-ethyl-3-methylimidazolium, 1-methyl-3-propylimidazolium, 1-methyl-3-isopropylimidazolium, 1-methyl-3-propylimidazolium, 1-methoxymethyl-3-methylimidazolium, 1-methyl-3-butylimidazolium, 1-methyl-3-pentylimidazolium, 1-methyl-3-hexylimidazolium, 1,3-diethylimidazolium, 1,2-dimethyl-3-ethylimidazolium, 1,2-dimethyl-3-propylimidazolium, 1,2-dimethyl-3-butylimidazolium, and 1,2-dimethyl-3-hexylimidazolium. Examples of pyrazolium cations include, but not limited to, 1,2-dimethylpyrazolium, 1-methyl-2-ethylpyrazolium, 1-propyl-2-methylpyrazolium, and 1-methyl-2-butylpyrazolium. Examples of pyridinium cations include, but not limited to, N-methylpyridinium, N-ethylpyridinium, N-propylpyridinium, N-methoxymethylpyridinium, N-isopropylpyridinium, N-butylpyridinium, N-pentylpyridinium, and N-hexylpyridinium. Examples of triazolium cations include, but not limited to, 1-methyltriazolium, 1-ethyltriazolium, 1-propyltriazolium, 1-isopropyltriazolium, 1-butyltriazolium, 1-pentyltriazolium, and 1-hexyltriazolium. Examples of pyridazinium cations include, but not limited to, 1-methylpyridazinium, 1-ethylpyridazinium, 1-propylpyridazinium, 1-isopropylpyridazinium, 1-methoxymethylpyridazinium, 1-butylpyridazinium, 1-pentylpyridazinium, and 1-hexylpyridazinium. Examples of thiazolium cations include, but not limited to, 1,2-dimethylthiazolium and 1,2-dimethyl-3-propylthiazolium. Examples of oxazolium cations include, but not limited to, 1-ethyl-2-methyloxazolium and 1,3-dimethyloxazolium. Examples of pyrimidinium cations include, but not limited to, 1,2-dimethylpyrimidinium and 1-methyl-3-propylpyrimidinium. Examples of pyrazinium cations include, but not limited to, 1-ethyl-2-methylpyrazinium and 1-butylpyrazinium.

Examples of anions for ammonium salts that may be used in the present invention include BF4-, PF6-, BF3CF3-, BF3C2F5-, BF3(CN)—, B(CN)4-, CF3SO3-, C2F5SO3-, C3F7SO3-, C4F9SO3-, N(SO2F)2-, N(CF3SO2)2-, N(C2F5SO2)2-, N(CF3SO2)(CF3CO)—, N(CF3SO2)(C2F5SO2)-, and N(CF3SO2)(FSO2)-.

The Y1-Y2 and X1-X2 directions shown in FIGS. 1A to 1C indicate two orthogonal directions in a plane (plane perpendicular to the thickness direction (Z1-Z2)). The Y1-Y2 direction is defined as the longitudinal direction. The Y1 direction is defined as the front direction. The Y2 direction is defined as the rear direction. The X1-X2 direction is defined as the lateral direction. The X1 direction is defined as the right direction. The X2 direction is defined as the left direction.

In the embodiment shown in FIGS. 1A to 1C, the device part 1a that forms the polymer actuator device 1 includes a fixed portion 5 located rearward in the Y2 direction and fixed and supported by a support (not shown). The polymer actuator device 1 shown in FIGS. 1A to 1C is cantilevered. The device part 1a further includes a bending portion 6 located forward of the fixed portion 5 in the Y1 direction. In this embodiment, the longitudinal direction (Y1-Y2) is the direction from the fixed portion 5 toward the bending portion 6 of the device part 1a. The fixed portion 5 and the bending portion 6 shown in FIGS. 1A to 1C are illustrative only and may be configured in other manners. For example, the fixed portion 5 may be located in the center of the device part 1a, and the bending portion 6 may be located on each side of the fixed portion 5 in the longitudinal direction.

As shown in FIG. 1A, the first electrode layer 3 has a width T1 in the lateral direction (X1-X2) and a length L1 in the longitudinal direction (Y1-Y2). The second electrode layer 4 has the same width T1 and length L1 as the first electrode layer 3.

As shown in FIG. 1A, the electrolyte layer 2 has a larger area than the first electrode layer 3 and has a larger width in the lateral direction (X1-X2) and a larger length in the longitudinal direction (Y1-Y2) than the first electrode layer 3. Although the electrolyte layer 2 may have substantially the same size as the first and second electrode layers 3 and 4, the electrolyte layer 2 preferably has a slightly larger size than the first and second electrode layers 3 and 4 to prevent a short circuit between the electrode layers at the ends thereof.

Although FIGS. 1A to 1C illustrate the first electrode layer 3, the second electrode layer 4, and the electrolyte layer 2 as being substantially rectangular in plan view, they may be configured in other shapes.

In this embodiment, as shown in FIGS. 1A and 1B, the device part 1a further includes a reference electrode layer 7 disposed between the first and second electrode layers 3 and 4 and in contact with the electrolyte layer 2.

The cross-section shown in FIG. 1B has a five-layer structure in which the electrolyte layer 2 is disposed between the reference electrode layer 7 and the first electrode layer 3 and between the reference electrode layer 7 and the second electrode layer 4. The cross-section shown in FIG. 1C has a three-layer structure including the first electrode layer 3, the electrolyte layer 2, and the second electrode layer 4 without the reference electrode layer 7 between the first and second electrode layers 3 and 4.

As shown in FIG. 1A, the reference electrode layer 7 has a width T2 in the lateral direction (X1-X2). In this embodiment, the width T2 is smaller than the width T1 of the first and second electrode layers 3 and 4.

In this embodiment, as shown in FIGS. 1A and 1B, the reference electrode layer 7 extends in the longitudinal direction (Y1-Y2), which is the direction from the fixed portion 5 toward the bending portion 6 of the device part 1a. The reference electrode layer 7 extends between both ends 1b and 1c of the device part 1a in the longitudinal direction. The reference electrode layer 7 also extends rearward (outward) (Y2) of the fixed portion 5 located in the rear of the device part 1a and forms a connection portion 7b for connection to a driving apparatus. As shown in FIGS. 1A and 1B, the front end surface 7a of the reference electrode layer 7 (the surface at the end of the bending portion 6) is substantially in flush with the front end surfaces 3a and 4a of the first and second electrode layers 3 and 4 (the surfaces at the end of the bending portion 6). The electrolyte layer 2 extends forward (outward) of the front end surface 7a of the reference electrode layer 7. The electrolyte layer 2a (labeled with reference numeral 2a to specify where the electrolyte layer 2 is located) located forward of the front end surface 7a of the reference electrode layer 7 is integrated with the electrolyte layer 2 between the reference electrode layer 7 and the first electrode layer 3, between the reference electrode layer 7 and the second electrode layer 4, and between the first and second electrode layers 3 and 4.

The reference electrode layer 7 is preferably made of the same material as the first and second electrode layers 3 and 4. In this embodiment, as described above, the first and second electrode layers 3 and 4 contain carbon nanotubes and an ionic liquid, and accordingly, the reference electrode layer 7 contains carbon nanotubes and an ionic liquid. In this embodiment, the first electrode layer 3, the second electrode layer 4, the reference electrode layer 7, and the electrolyte layer 2 preferably contain the same ionic liquid.

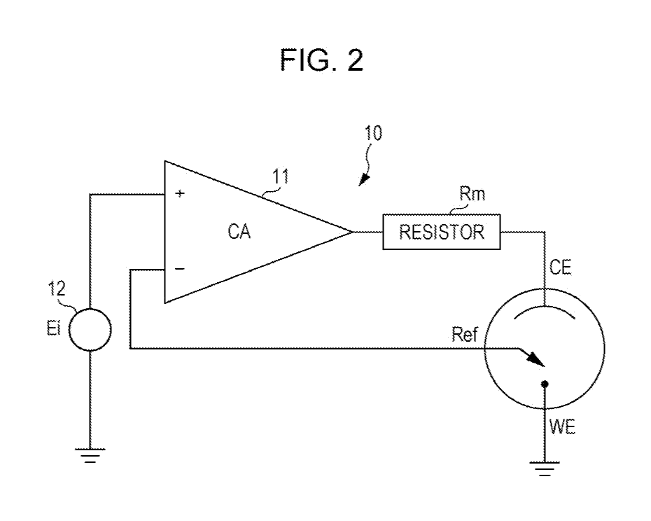

The polymer actuator device 1 according to this embodiment is connected to a potentiostat 10 shown in FIG. 2. One of the first and second electrode layers 3 and 4 serves as a working electrode (WE) of the potentiostat 10, whereas the other of the first and second electrode layers 3 and 4 serves as a counter electrode (CE). In FIG. 2, the reference electrode layer 7 serves as a reference electrode (Ref). The reference electrode layer 7 (Ref) is an electrode that serves as a reference for determining the potential of the working electrode (WE) in the potentiostat 10.

The potentiostat 10 includes an operational amplifier circuit 11 having a non-inverting input (+), an inverting input (−), and an output. As shown in FIG. 2, the output is connected to the counter electrode (CE) via a resistor Rm. The inverting input (−) is connected to the reference electrode layer 7 (Ref). The non-inverting input (+) is connected to an input voltage source 12.

In the following description, the first electrode layer 3 is assumed to be the working electrode (WE), and the second electrode layer 4 is assumed to be the counter electrode (CE). The potentiostat 10 shown in FIG. 2 is used to drive the polymer actuator device 1 according to this embodiment. The reference electrode layer 7 has a substantially fixed reference potential (self-potential). The potential of the working electrode (WE) is regulated based on the reference potential. Specifically, the potential of the first electrode layer 3, which serves as the working electrode (WE), is regulated at a predetermined level or within a predetermined range relative to the potential of the reference electrode layer 7. The device part 1a is driven, for example, by an alternating current (AC-driven) to bend the bending portion 6 upward (Z1) and downward (Z2).

An example of AC driving is illustrated below. For example, a rectangular wave voltage alternating between +1.15 and −1.35 V at a frequency of 5 mHz is applied between the first electrode layer 3, serving as the working electrode (WE), and the reference electrode layer 7. When voltages of +1.15 and −1.35 V are applied between the first electrode layer 3 and the reference electrode layer 7, the potentiostat 10 in FIG. 2 provides a voltage (potential difference) of ±2.5 V between the first electrode layer 3, serving as the working electrode (WE), and the second electrode layer 4, serving as the counter electrode (CE). A voltage of +1.15 V applied between the first electrode layer 3 and the reference electrode layer 7 causes the bending portion 6 to bend, for example, upward (Z1) as ion migration through the electrolyte layer 2 causes the two electrodes 3 and 4 to swell to different extents. A voltage of −1.35 V applied between the first electrode layer 3 and the reference electrode layer 7 causes the bending portion 6 to bend, for example, downward (Z2). It should be understood that the relationship between the applied voltage and the bending direction may be opposite to the above relationship. Although it is generally believed that the mechanism by which ion migration causes the two electrodes 3 and 4 to swell to different extents is not uniquely determined, it is known that one possible factor for swelling to different extents is the difference in ionic radius between cations and anions.

According to this embodiment, the device part 1a can be driven at constant potential because the voltage (potential difference) between the first and second electrode layers 3 and 4 is regulated based on the reference potential of the reference electrode layer 7. In the above example, the device part 1a can be driven at constant potential both when a voltage of +2.5V is applied between the first and second electrode layers 3 and 4 and when a voltage of −2.5V is applied between the first and second electrode layers 3 and 4. This prevents a potential shift such as occurs in a two-electrode structure in the related art. Thus, the displacement position (displacement) H1 reached by the device part 1a when a voltage of +2.5V is periodically applied between the first and second electrode layers 3 and 4 is substantially constant, and the displacement position (displacement) H2 reached by the device part 1a when a voltage of −2.5V is periodically applied between the first and second electrode layers 3 and 4 is substantially constant (see FIG. 1B). In addition, the absolute values of the displacement (H1) to the displacement position H1 and the displacement (−H2) to the displacement position H2 from the initial position indicated by the solid line in FIG. 1B, which is assumed to be at a height of zero, are substantially equal. The terms “displacement position H1” and “displacement position H2” refer to the positions reached by the device part 1a when it bends to the maximum displacement from the initial position.

In the above example, the positive voltage applied between the first electrode layer 3 and the reference electrode layer 7 is +1.15 V, and the negative voltage applied between the first electrode layer 3 and the reference electrode layer 7 is −1.35 V. These voltages are not one half of ±2.5 V, i.e., +1.25 V and −1.25 V, because the reference potential (self-potential) of the reference electrode layer 7 is not 0 V. Even if the reference potential of the reference electrode layer 7 is unknown, the potential of the first electrode layer 3 relative to the reference electrode layer 7 can be controlled, for example, by measuring the current flowing between the first and second electrode layers 3 and 4. It should be noted that no current flows through the reference electrode layer 7.

The absolute values of the displacements (H1) and (−H2) may be varied depending on the input voltage from the input voltage source 12.

In a two-electrode structure in the related art, the potential might not return to the original reference level after the removal of the voltage applied between the first and second electrode layers because of a potential shift. In the three-electrode structure according to this embodiment, the potential can be properly returned to the initial level (reference level). Thus, the device part 1a can be properly returned to the initial position (reference position) indicated by the solid line in FIG. 1B.

In this embodiment, the electrode layers 3, 4, and 7 and the electrolyte layer 2 that form the device part 1a preferably contain the same ionic liquid. This allows the driving potential for the device part 1a to be properly set within the potential window of the ionic liquid. The potential window of the ionic liquid is known to a certain extent; therefore, in this embodiment, the driving potential can be properly controlled within the potential window of the ionic liquid. In addition, a potential shift can be properly prevented, for example, after extended use because the reference potential of the reference electrode layer 7 is substantially fixed. This inhibits the electrolysis of the ionic liquid and thus allows stable operating characteristics (e.g., stable displacement position during bending and stable return position).

In particular, the potential window of the ionic liquid is narrowed in a configuration including electrode layers containing carbon nanotubes, which have a large specific surface area and various active sites. In this embodiment, the use of a potentiostat including a working electrode, a counter electrode, and a reference electrode allows the driving potential to be properly controlled even within such a narrow potential window. Thus, the polymer actuator device 1 can be stably driven with a large displacement and also has an extended life.

In this embodiment, as shown in FIG. 1A, the width T2 of the reference electrode layer 7 in the lateral direction (X1-X2) is smaller than the width T1 of the first and second electrode layers 3 and 4. Thus, as shown in FIG. 1C, the polymer actuator device 1 has a three-layer structure in which the first and second electrode layers 3 and 4 are disposed opposite each other with the electrolyte layer 2 therebetween on each side of the reference electrode layer 7. This allows ions to migrate properly between the first and second electrode layers 3 and 4 and thus allows the bending portion 6 to bend properly when a voltage is applied thereto.

In this embodiment, the reference electrode layer 7 has a smaller area than the first and second electrode layers 3 and 4. The area of the reference electrode layer may be reduced by reducing the width T2, as described above, or may be reduced in other manners. For example, one or more slits or through-holes extending through the reference electrode layer 7 across the thickness may be formed while the width T2 of the reference electrode layer 7 is substantially equal to the width T1 of the first and second electrode layers 3 and 4. This allows the reference electrode layer 7 to have a smaller area than the first and second electrode layers 3 and 4. Nevertheless, the reference electrode layer 7 has a simpler shape if the width T2 is reduced. The width T2 of the reference electrode layer 7 is preferably about 20% to 60% of the width T1 of the first and second electrode layers 3 and 4.

In this embodiment, as shown in FIGS. 1A and 1B, the reference electrode layer 7 extends from the fixed portion 5 to the bending portion 6 of the device part 1a. The reference electrode layer 7 is preferably made of a flexible material so that it does not interfere with the bending motion of the bending portion 6. In this embodiment, the reference electrode layer 7 may be made of the same material as the first and second electrode layers 3 and 4, and all of the first electrode layer 3, the second electrode layer 4, and the reference electrode layer 7 may be made of a flexible material. Because the reference electrode layer 7 extends to the bending portion 6, a potential shift can be effectively prevented in the bending portion 6, thus providing more stable operating characteristics.

In this embodiment, as shown in FIGS. 1A and 1B, the front end surface 7a of the reference electrode layer 7 (the surface at the end of the bending portion 6) is substantially in flush with the front end surfaces 3a and 4a of the first and second electrode layers 3 and 4 (the surfaces at the end of the bending portion 6). The electrolyte layer 2a extends forward (outward) of the front end surface 7a of the reference electrode layer 7. Thus, the electrolyte layer 2a covers the front end surface 7a of the reference electrode layer 7. This prevents a short circuit between the first electrode layer 3, the second electrode layer 4, and the reference electrode layer 7 near the front end surfaces 3a, 4a, and 7a thereof. After the stacking of each layer and the pressing of the device part 1a, the distances between the first electrode layer 3 and the reference electrode layer 7 and between the second electrode layer 4 and the reference electrode layer 7 (see FIG. 1B) are shorter than the distance between the first and second electrode layers 3 and 4 without the reference electrode layer 7 therebetween (see FIG. 1C). The structure shown in FIGS. 1A and 1B prevents a short circuit between the first electrode layer 3, the second electrode layer 4, and the reference electrode layer 7 near the front end surfaces 3a, 4a, and 7a thereof after the pressing step. As shown in FIGS. 1A and 1B, the electrolyte layer 2 also protrudes rearward (outward) of the rear end surfaces 3b and 4b of the first and second electrode layers 3 and 4 (the surfaces at the end of the fixed portion 5) at the rear end 1c of the device part 1a. This prevents a short circuit between the first electrode layer 3, the second electrode layer 4, and the reference electrode layer 7 near the rear end surfaces 3b, 4b, and 7b thereof.

The polymer actuator device 1 according to this embodiment may be DC-driven rather than AD-driven. In either case, a potential shift such as occurs in a two-electrode structure in the related art can be prevented, thus providing stable operating characteristics.

### EXAMPLES

### Cyclic Voltammetry (CV) with Varying Widths of Reference Electrode Layer

In this experiment, the width T1 of the first and second electrode layers 3 and 4 shown in FIG. 1A was 5 mm, and the length L1 thereof was 10 mm. The length of the reference electrode layer 7 was fixed at 10 mm Cyclic voltammetry (CV) was performed with varying widths T2 within the range of 0 to 5 mm.

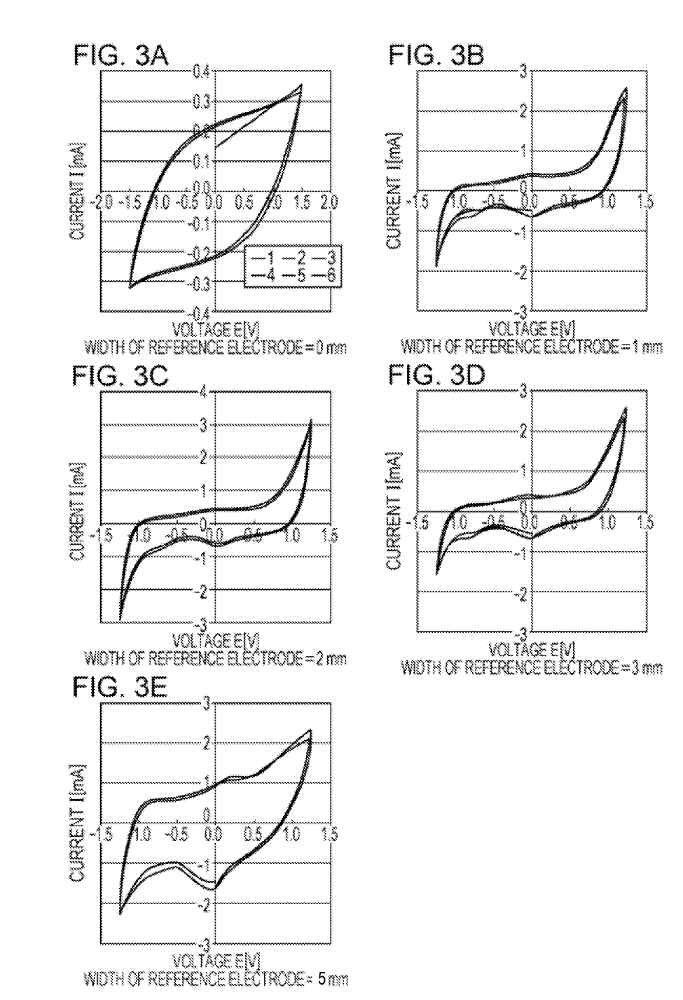

FIGS. 3A to 3E are cyclic voltammograms (CV) obtained with varying widths T2 of the reference electrode layer 7. FIG. 3A is a cyclic voltammogram (CV) of a two-electrode structure including a reference electrode layer 7 having a width T2 of 0 mm, i.e., no reference electrode layer 7. FIG. 3B is a cyclic voltammogram (CV) of a three-electrode structure including a reference electrode layer 7 having a width T2 of 1 mm FIG. 3C is a cyclic voltammogram (CV) of a three-electrode structure including a reference electrode layer 7 having a width T2 of 2 mm FIG. 3D is a cyclic voltammogram (CV) of a three-electrode structure including a reference electrode layer 7 having a width T2 of 3 mm. FIG. 3E is a cyclic voltammogram (CV) of a three-electrode structure including a reference electrode layer 7 having a width T2 of 5 mm.

The cyclic voltammograms (CV) in FIGS. 3B to 3D were substantially identical. The cyclic voltammograms (CV) in FIGS. 3B to 3D, which were obtained from three-electrode structures, differed from the cyclic voltammogram (CV) in FIG. 3A, which was obtained from a two-electrode structure, and the cyclic voltammogram (CV) in FIG. 3E, which was obtained from a three-electrode structure including a reference electrode layer 7 having the same size as the first and second electrode layers 3 and 4. This difference between the cyclic voltammograms (CV) is attributed to, for example, the ease of migration of the ionic liquid to which a voltage was applied and the presence or absence of the electrolysis of the ionic liquid. FIGS. 3B to 3D show that stable operating characteristics were achieved. The widths T2 of the reference electrode layer 7 in FIGS. 3B to 3D were 20% to 60% of the width T1 of the first and second electrode layers 3 and 4.

Cyclic Voltammetry (CV) with Varying Lengths of Reference Electrode Layer

An experiment was conducted with varying lengths of the reference electrode layer 7 in the structure shown in FIGS. 1A to 1C in the longitudinal direction (Y1-Y2).

In this experiment, a cyclic voltammogram (CV) substantially identical to those in FIGS. 3B to 3D was obtained from a structure in which the reference electrode layer 7 extended from the rear end 1c toward the front end 1b of the device part 1a by at least one third the distance therebetween. A cyclic voltammogram (CV) obtained from a structure in which the length of the reference electrode layer 7 was less than one third was similar to that in FIG. 3A.

Examples of optimum thicknesses were as follows: the optimum thicknesses of the first and second electrode layers 3 and 4 were 112 μm, the optimum thickness of the reference electrode layer 7 was 40 μm, the optimum thickness between the first electrode layer 3 and the reference electrode layer 7 was 21 μm, and the optimum thickness between the second electrode layer 4 and the reference electrode layer 7 was 23 μm (see FIG. 1B). The above thicknesses were measured before pressing; the total thickness after pressing was 262 μm.

### Cyclic Voltammetry (CV) on Inventive Example and Comparative Examples with Different Three-Electrode Structures

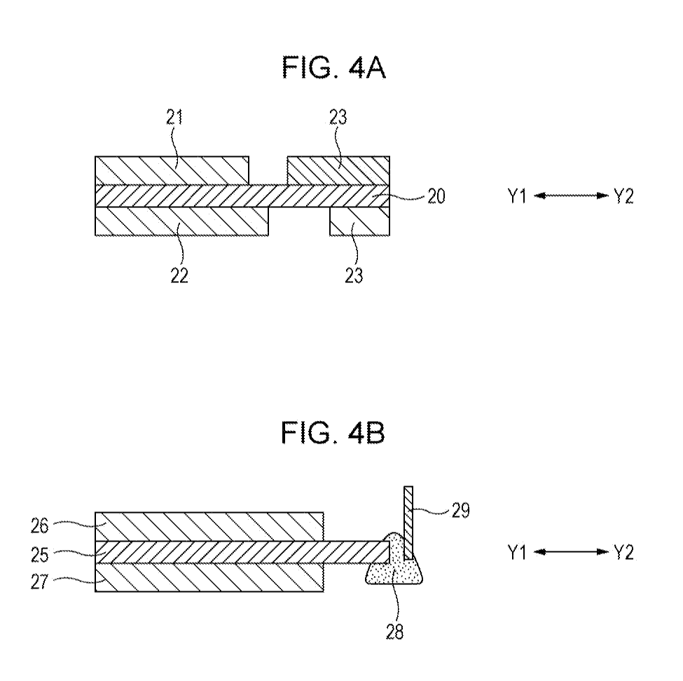

In Comparative Example 1, a polymer actuator device having the structure shown in FIG. 4A (longitudinal sectional view) was fabricated. The polymer actuator device of Comparative Example 1 included first and second electrode layers 21 and 22 disposed on either surface of an electrolyte layer 20. The first and second electrode layers 21 and 22 were both located only on the Y1 side. Reference electrode layers 23 were disposed on the surfaces of the electrolyte layer 20 on the empty side, i.e., the Y2 side.

In Comparative Example 2, a polymer actuator device having the structure shown in FIG. 4B (longitudinal sectional view) was fabricated. The polymer actuator device of Comparative Example 2 included first and second electrode layers 26 and 27 disposed on either surface of an electrolyte layer 25. A reference electrode layer 29 made of a platinum wire was disposed on a portion of the electrolyte layer 25 protruding in the Y2 direction with an ionic liquid 28 therebetween.

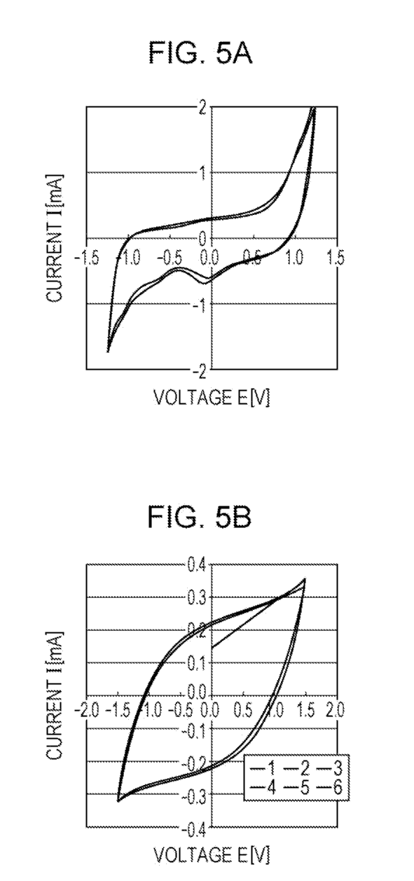

FIG. 5A is a cyclic voltammogram (CV) of an inventive example having the structure shown in FIGS. 1A to 1C. FIG. 5B is a cyclic voltammogram (CV) of Comparative Example 1 in FIG. 4A. Comparative Example 2 in FIG. 5C exhibited unstable characteristics due to the flow of the ionic liquid 28. As shown in FIG. 5B, the cyclic voltammogram (CV) of Comparative Example 1 was substantially identical to that in FIG. 3A, demonstrating that the reference electrode layers 23 did not contribute to improved characteristics.

### Experiment on Displacement of and Current Through Three-Electrode Structure (Inventive Example) and Two-Electrode Structure (Comparative Example)

In an inventive example, a polymer actuator device having the three-electrode structure in FIGS. 1A to 1C was fabricated. In a comparative example, a polymer actuator device having a two-electrode structure in which the reference electrode layer 7 in FIGS. 1A to 1C was omitted was fabricated.

The polymer actuator device of the inventive example was AC-driven by applying a rectangular wave voltage (potential difference) alternating between +1.15 and −1.35 V at a frequency of 5 mHz between the reference electrode layer 7 and the first electrode layer 3, serving as the working electrode. Thus, a voltage of ±2.5V was applied between the first and second electrode layers.

The polymer actuator device of the comparative example was AC-driven by applying a rectangular wave voltage of ±2.5V at a frequency of 5 mHz between the first and second electrode layers.

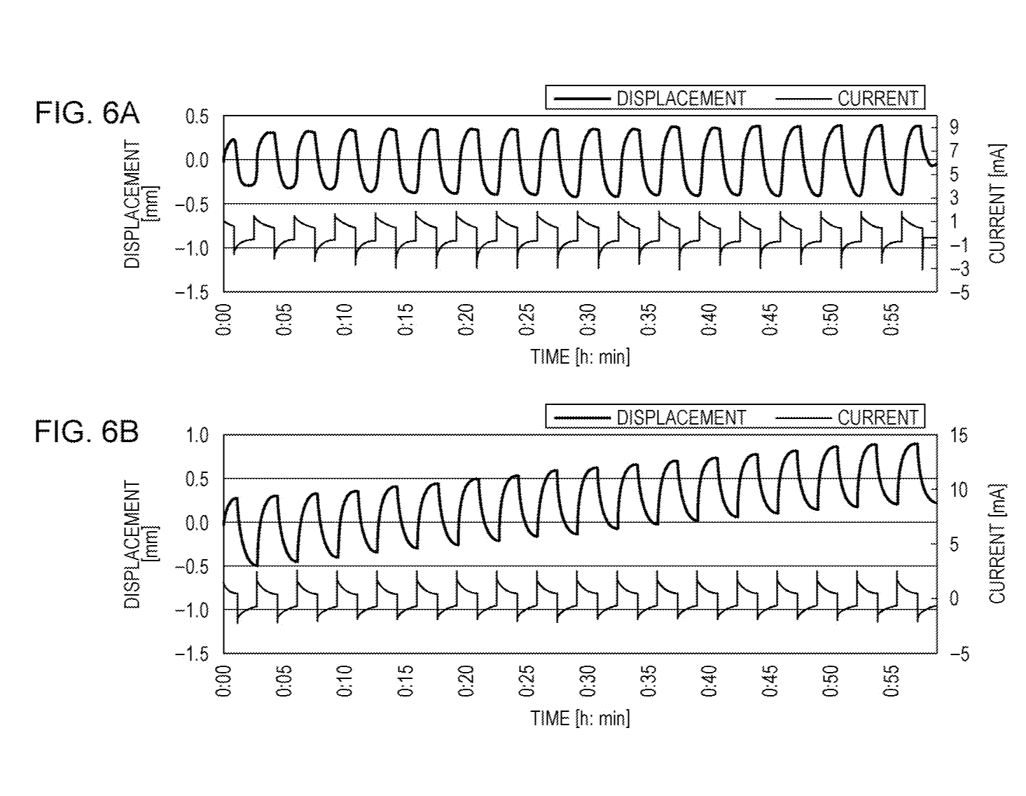

The displacement and the current that flowed between the first and second electrode layers of each polymer actuator device were measured. The experimental results are shown in FIGS. 6A and 6B. FIG. 6A shows the experimental results of the inventive example, and FIG. 6B shows the experimental results of the comparative example.

As shown in FIG. 6B, the comparative example exhibited a shift in displacement position. In contrast, the inventive example in FIG. 6A was significantly stable in displacement position.

1. A polymer actuator device including a device part, the device part comprising:
an electrolyte layer;
first and second electrode layers disposed on first and second surfaces of the electrolyte layer, respectively, in a thickness direction; and
a reference electrode layer disposed between the first and second electrode layers and in contact with the electrolyte layer,
wherein the device part is configured to bend in response to a voltage applied between the first and second electrode layers.

2. The polymer actuator device according to claim 1, wherein the reference electrode layer has an area smaller than that of the first and second electrode layers.

3. The polymer actuator device according to claim 2, wherein
the device part includes a fixed portion at one end thereof at which the device part is fixed and supported, and a bending portion at another end thereof,
the reference electrode layer extends in a longitudinal direction from the fixed portion toward the bending portion, and
a width of the reference electrode layer is smaller than that of the first and second electrode layers, the width being in a lateral direction perpendicular to the longitudinal direction.

4. The polymer actuator device according to claim 1, wherein the device part has a portion having a five-layer structure in which a first part of the electrolyte layer is disposed between the reference electrode layer and the first electrode layer and a second part of the electrolyte layer is disposed between the reference electrode layer and the second electrode layer.

5. The polymer actuator device according to claim 1, wherein the reference electrode layer is formed of a flexible material.

6. The polymer actuator device according to claim 5, wherein
the device part includes a fixed portion at one end thereof and a bending portion at another end thereof, and
the reference electrode layer extends between the one end and the another end.

7. The polymer actuator device according to claim 6, wherein
the reference electrode layer further extends beyond the fixed portion,
an end surface of the reference electrode layer in the bending portion is substantially flush with end surfaces of the first and second electrode layers in the bending portion, and
the electrolyte layer extends beyond the end surface of the reference electrode layer in the bending portion and extends beyond other end surfaces of the first and second electrode layers in the fixed portion.

8. The polymer actuator device according to claim 1, wherein the first electrode layer, the second electrode layer, and the reference electrode layer are formed of a same material.

9. The polymer actuator device according to claim 8, wherein the first electrode layer, the second electrode layer, and the reference electrode layer contain carbon nanotubes.

10. The polymer actuator device according to claim 1, wherein the first electrode layer, the second electrode layer, the reference electrode layer, and the electrolyte layer contain a same ionic liquid.

11. An apparatus for driving a polymer actuator device, comprising:
the polymer actuator device according to claim 1; and
a potentiostat configured to drive the device part, wherein one of the first and second electrode layers serves as a working electrode, the other of the first and second electrode layers serves as a counter electrode, and the reference electrode layer has a reference potential.

12. The apparatus for driving a polymer actuator device according to claim 11, wherein the device part is driven at a constant potential.

13. A method for driving the polymer actuator device of claim 1, comprising:
driving the device part of the polymer actuator device using a potentiostat, wherein one of the first and second electrode layers serves as a working electrode, the other of the first and second electrode layers serves as a counter electrode, and the reference electrode layer has a reference potential.

14. The method for driving a polymer actuator device according to claim 13, wherein the device part is driven at a constant potential.

15. The polymer actuator device according to claim 4, wherein the device part has a remaining portion having a three-layer structure without the reference electrode layer, in which the electrolyte layer is disposed between the first electrode layer and the second electrode layer.
